(19) United States
(12) Patent Application Publication
(10) Pub. No.: US 2009/0310321 A1
(43) Pub. Date: Dec. 17, 2009

(54) PRINTED CIRCUIT BOARD AND ELECTRONIC APPARATUS

(75) Inventors: Takahiro SUGAI, Tokyo (JP); Ichioh MURAKAMI, Tokyo (JP); Minoru TAKIZAWA, Tokyo (JP); Takahisa FUNAYAMA, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/399,779

(22) Filed: Mar. 6, 2009

(30) Foreign Application Priority Data
Jun. 16, 2008 (JP) 2008-156455

(51) Int. Cl. H05K 7/00

(52) U.S. Cl. 361/783

(57) ABSTRACT

According to an aspect of the present invention, there is provided a printed circuit board including: a semiconductor package having a surface and a plurality of solder bumps arranged on the surface; a wiring board having electrodes provided at positions respectively corresponding to the solder bumps and configured to mount the semiconductor package; and a reinforcing member formed continuously along the surface and configured to fix the semiconductor package to the wiring board; wherein the reinforcing member is configured to define an opening portion between the surface and the wiring board.

### CROSS-REFERENCE TO RELATED APPLICATIONS

This application is based upon and claims the benefit of priority from Japanese Patent Application No. 2008-156455, filed on Jun. 16, 2008, the entire contents of which are incorporated herein by reference.

### BACKGROUND

1. Field

An aspect of the present invention relates to a printed circuit board and an electronic apparatus.

2. Description of the Related Art

Conventionally, there is known a printed circuit board in which a semiconductor package mounting board is fixed over a whole periphery of a semiconductor package through a reinforcing member (see JP-A-2003-197681, for instance).

The printed circuit board includes a semiconductor package having a semiconductor element mounted on a semiconductor element mounting board and a plurality of electrodes to be fused and bonded to a solder bump on an opposed face to a semiconductor element mounting face, a semiconductor package mounting board having an electrode provided opposite to the electrode provided on the semiconductor package, the solder bump for electrically connecting the electrodes of the semiconductor package and the semiconductor package mounting board through a fusion by a reflow, and a reinforcing member disposed on an outside of the solder bump and serving to fix the semiconductor package to the semiconductor package mounting board at a proper interval over a whole periphery of a side face of the semiconductor package, and a mounting interval between the semiconductor package and the semiconductor package mounting board can be held. In a case in which a stress is applied to the solder bump due to a difference in a coefficient of expansion between the semiconductor package and the semiconductor package mounting board with a rise in a temperature of the printed circuit board, therefore, it is possible to absorb the stress, thereby preventing a crack from being generated in the solder bump.

According to the conventional printed circuit board, however, the reinforcing member is disposed at a proper interval in order to radiate heat between the semiconductor package and the semiconductor package mounting board. By providing the interval, it is possible to relieve the difference in the coefficient of thermal expansion. Consequently, it is possible to reduce the stress applied to the solder bump due to the difference in the coefficient of thermal expansion between the semiconductor package and the semiconductor package mounting board. However, it is impossible to always achieve a sufficient strength for reducing an external force generated by dropping of an electronic apparatus including the printed circuit board.

### BRIEF DESCRIPTION OF THE SEVERAL VIEWS OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 is an exemplary schematic view showing an appearance of an electronic apparatus according to an embodiment of the invention;

FIG. 2 is an exemplary perspective view showing a configuration of a printed circuit board of the electronic apparatus according to the embodiment; and

FIGS. 3A and 3B are schematic views showing a configuration of the printed circuit board of the electronic apparatus according to the embodiment, wherein FIG. 3A is a plan view and FIG. 3B is a sectional view taken along a line IIIB-IIIB of FIG. 3A.

### DETAILED DESCRIPTION

Various embodiments according to the present invention will be described hereinafter with reference to the accompanying drawings. In general, according to an aspect of the present invention, there is provided a printed circuit board including: a semiconductor package having a surface and a plurality of solder bumps arranged on one face thereof; a wiring board having electrodes provided at positions respectively corresponding to the solder bumps and configured to mount the semiconductor package; and a reinforcing member formed continuously along the surface and configured to fix the semiconductor package to the wiring board; wherein the reinforcing member is configured to define an opening portion between the surface and the wiring board.

An embodiment of a printed circuit board and an electronic apparatus according to the invention will be described below in detail with reference to the drawings.

(Configuration of Electronic Apparatus)

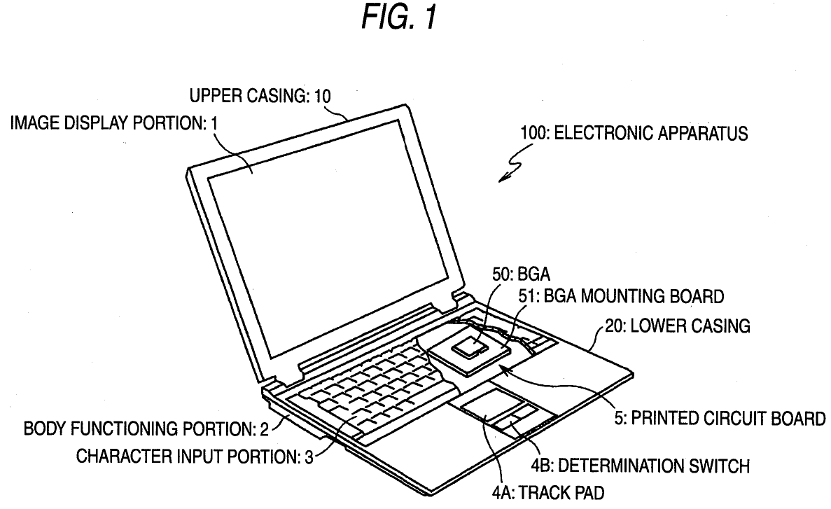

FIG. 1 is a schematic view showing an appearance of an electronic apparatus according to the embodiment of the invention.

An electronic apparatus 100 is configured of an upper casing 10 and a lower casing 20, and the upper casing 10 and the lower casing 20 are openably connected through a hinge portion. The lower casing 20 has a printed circuit board 5 as a body functioning portion 2 located internally and has a character inputting portion 3, a track pad 4A to be a pointing device and a determination switch 4B on an upper face 20a. The printed circuit board 5 mounts a Ball Grid Array (BGA) 50 to be a semiconductor package, an electronic component such as a Central Processing Unit (CPU) on a BGA mounting board 51 to be a semiconductor package mounting board and connecting a Hard Disc Drive (HDD) through a connector. The character inputting portion 3, such as a keyboard, serves to input characters and commands.

Moreover, a left side face, a right side face, a front face and a back face to form faces of the lower casing 20 are provided with a connector terminal such as a Universal Serial Bus (USB) port and a Local Area Network (LAN) port which are not shown. The upper casing 10 has, on a front face, an image display portion 1 formed by a liquid crystal display panel for displaying a character or an image.

(Configuration of Fingerprint Reading Portion)

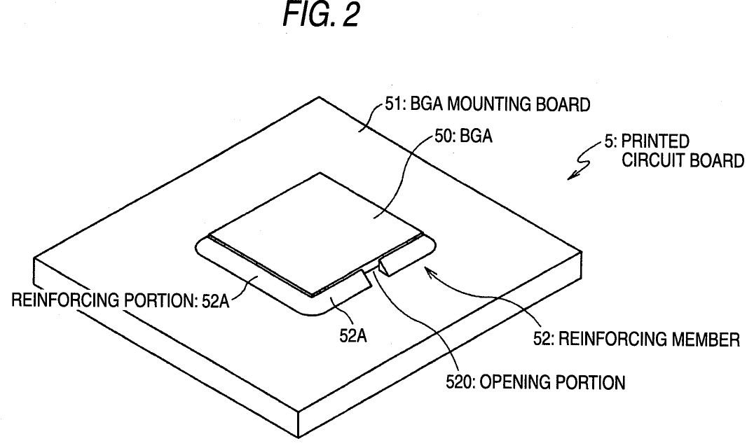

FIG. 2 is a perspective view showing a configuration of a printed circuit board of the electronic apparatus according to the embodiment of the invention.

The printed circuit board 5 has the BGA 50 for mounting and packaging semiconductor elements on a ceramic board, the BGA mounting board 51 for mounting the BGA 50 through a solder ball to be a solder bump which will be described below, and a reinforcing member 52 provided partially with an opening portion 520 and formed continuously around the BGA 50, and serving to reinforce mounting on the BGA mounting board 51 through a reinforcing portion 52A formed from each of four sides around the BGA 50 to a face of the BGA mounting board 51 on an outside of the BGA 50.

The BGA 50 is a CPU, for example, and has a plurality of electrodes on a bottom face.

The BGA mounting board 51 is formed of a plate material such as glass epoxy, and has electrodes in corresponding positions to the electrodes provided on the bottom face of the BGA 50 of a BGA mounting face and electrically connects the electrodes to each portion in the electronic apparatus 100 through a printed circuit wiring.

The reinforcing member 52 is formed of an epoxy resin, a UV curing resin or a thermosetting resin. The reinforcing member 52 is formed by applying and curing the resin on side faces of the BGA 50 and a mounting face of the BGA mounting board 51. Moreover, the reinforcing member 52 is formed by providing a non-application region having a width of approximately 5 mm, for example, as the opening portion 520 of the reinforcing portion 52A in a part around the BGA 50.

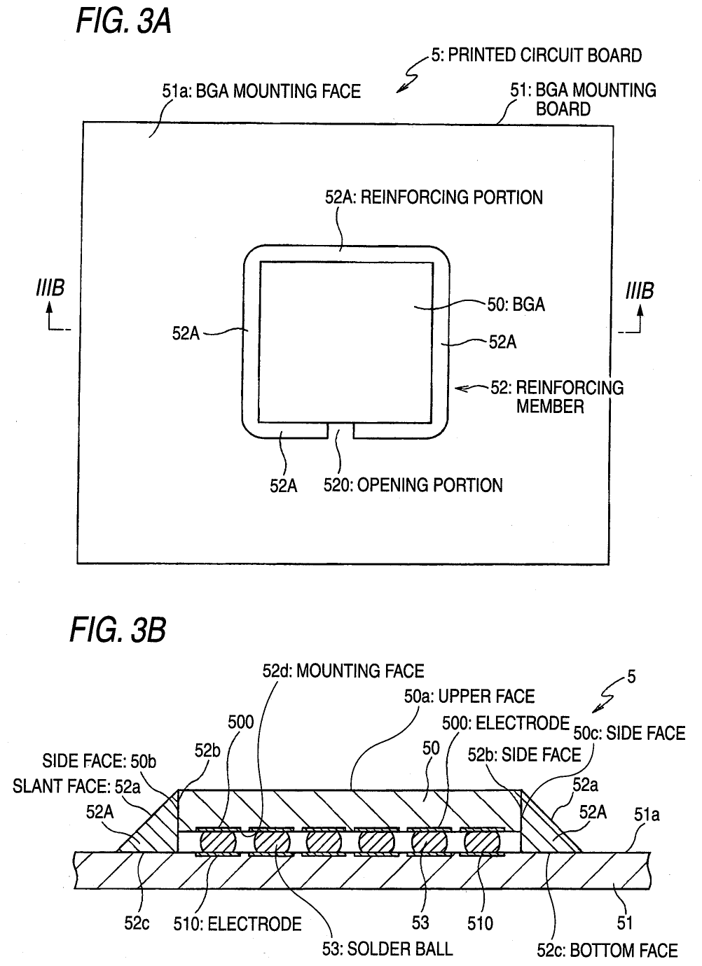

FIGS. 3A and 3B are schematic views showing a configuration of the printed circuit board of the electronic apparatus according to the embodiment of the invention. FIG. 3A is a plan view and FIG. 3B is a sectional view taken along a line IIIB-IIIB of FIG. 3A.

The BGA 50 includes an upper face 50a having a size of approximately 35×35 mm, side faces 50b and 50c having a thickness of approximately 2 mm, and a mounting face 50d having approximately 300 electrodes 500, for example.

The BGA mounting board 51 includes a BGA mounting face 51a having a plurality of electrodes 510 with disposing positions which are coincident with those of the electrodes 500 in an corresponding region to the mounting face 50d of the BGA 50. The electrodes 500 and the electrodes 510 are electrically connected through a solder ball 53, respectively. A solder bump formed by screen printing may be used in place of the solder ball 53.

The reinforcing member 52 preferably takes a triangular sectional shape having a slant face 52a, a side face 52b and a bottom face 52c in order to achieve a sufficient strength. The side face 52b is formed in contact with the side faces 50c and 50b of the BGA 50, and the bottom face 52c is formed on an outside of a region of the BGA mounting face 51a which is corresponding to the mounting face 50d.

The reinforcing member 52 may cover the upper face 50a within a range in which the mounting of the semiconductor element disposed on the upper face 50a is not disturbed. Moreover, the reinforcing member 52 may cover the region of the BGA mounting face 51a which is opposed to the mounting face 50d so as not to come in contact with the solder ball 53 and the electrode 510. Moreover, the slant face 52a may be formed by a curved face in the section of FIG. 3B.

The opening portion 520 is preferably provided in a central part on one of four sides forming a periphery of the upper face 50a of the BGA 50. A width of the opening portion 520 is determined based on a length of one of the sides of the BGA 50. There is provided the reinforcing member 52 capable of sufficiently preventing a crack of the solder ball 53 disposed in the vicinity of both ends on one side also when a shock is applied by an external force, and the opening portion 520 is provided in the residual region. For example, when one side is 35 mm, the reinforcing member 52 is provided on both ends at an interval of 15 mm and residual 5 mm is set to be the opening portion 520.

(Manufacturing Process)

A process for manufacturing the electronic apparatus according to the embodiment of the invention will be described below with reference to the drawings.

First of all, the BGA 50 is disposed on the BGA mounting board 51 together with the solder ball 53. Next, the solder ball 53 is fused by a reflow to electrically connect the electrodes 500 and 510, thereby mounting the BGA 50 on the BGA mounting board 51.

Next, the reinforcing member 52 obtained before curing is applied around the BGA 50. In this case, a non-application region is provided as the opening portion 520 on one of the four sides.

Subsequently, a treatment such as an application of a curing agent, a UV irradiation or heating is carried out based on a type of the reinforcing member 520 to cure the reinforcing member 520, thereby forming the reinforcing portion 52A on each side around the BGA 50.

### ADVANTAGE OF THE EMBODIMENT

According to the embodiment, the mounting on the BGA mounting board 51 is reinforced by the reinforcing portion 52A for reinforcing the mounting on the BGA mounting board 51 through the reinforcing portion 52A except for one of the sides around the BGA 50 and the reinforcing portion 52A provided with the opening portion 520 to which the reinforcing member 52 is not applied at one side. Therefore, it is possible to achieve a sufficient durability for a shock caused by dropping of the electronic apparatus 100. In addition, by relieving heat generated in the BGA 50 through the opening portion 520, it is possible to prevent a defect such as the crack of the solder ball 53.

Although the BGA has been described in the embodiment, the invention can be applied to a Chip Size Package (CSP) or a package of a bare chip in the same manner.

What is claimed is:

1. A printed circuit board comprising:
a semiconductor package comprising a surface, and a plurality of solder bumps on the surface;
a wiring board comprising electrodes at positions respectively corresponding to the solder bumps and configured to mount the semiconductor package; and
an adhesive portion along the surface, configured to bond the semiconductor package to the wiring board;
wherein the adhesive portion is configured to define an opening portion between the surface and the wiring board.

2. The printed circuit board of claim 1, wherein:
the surface comprises a plurality of sides;
the adhesive portion comprises an adhesive area on each of the plurality of sides; and
the opening portion is at a center of the adhesive area.

3. The printed circuit board of claim 2, wherein the adhesive area is configured to cover at least one of the plurality of sides and at least a portion of a mounting face of the wiring board, where the semiconductor package is mounted.

4. A printed circuit board comprising:
a semiconductor package comprising a surface and a plurality of solder bumps on the surface;
a semiconductor package mounting board comprising electrodes at positions respectively corresponding to the solder bumps and configured to mount the semiconductor package; and
an adhesive portion along the surface and configured to attach the semiconductor package to the semiconductor package mounting board;
wherein the adhesive portion is configured to define an opening portion between the surface and the semiconductor package mounting board, and the opening portion is at a center of the adhesive portion.

5. An electronic apparatus comprising a printed circuit board comprising:
a semiconductor package comprising a surface and a plurality of solder bumps on the surface;
a wiring board comprising electrodes at positions respectively corresponding to the solder bumps and configured to mount the semiconductor package; and
an adhesive portion along the surface and configured to attach the semiconductor package to the wiring board;
wherein the adhesive portion is configured to define an opening portion between the surface and the wiring board.
